(19) United States
(12) Patent Application Publication
(10) Pub. No.: US 2021/0194212 A1
(43) Pub. Date: Jun. 24, 2021

(54) VCSELS INCLUDING A SUB-WAVELENGTH GRATING FOR WAVELENGTH LOCKING

(71) Applicant: ams Sensors Asia Pte. Ltd., Singapore (SG)

(72) Inventors: Chuni Ghosh, West Windsor, NJ (US); Jean-Francois Seurin, Princeton Junction, NJ (US); Maik Scheller, Redmond, WA (US)

(21) Appl. No.: 17/269,086

(22) PCT Filed: Aug. 26, 2019
(86) PCT No.: PCT/SG2019/050419

§ 371 Date: Feb. 17, 2021

Related U.S. Application Data
(60) Provisional application No. 62/724,833, filed on Aug. 30, 2018.

(51) Int. Cl. H01S 5/183; G01S 7/481

(52) U.S. Cl. CPC H01S 5/18361; G01S 7/4814; H01S 5/18305

(57) ABSTRACT

A VCSEL includes a substrate, and an epitaxial VSCEL structure on the substrate. The epitaxial VSCEL structure includes a resonant cavity, including a gain region, disposed between a first reflector and a partially reflecting second reflector. At least one of the first or second reflectors includes a first sub-wavelength grating to provide spectral control for optical emission from the VCSEL. The first sub-wavelength grating can be operable to lock a wavelength of an optical beam for emission from the VCSEL substantially to a wavelength defined by the grating.

### FIELD OF THE DISCLOSURE

The present disclosure relates to vertical-cavity surface-emitting lasers (VCSELs) that include a sub-wavelength grating for wavelength locking.

### BACKGROUND

Lasers, such as VCSELs, can be used in a wide range of applications including, for example, distance and ranging applications, as well as applications involving high-speed digital communications over fiber optic links. The temperature dependence of the lasing wavelength of laser devices is an important issue because the VCSELs are used in different environments with varying thermal conditions. For example, modern optical communication systems for military, aerospace and other applications may need to operate in a wide range of temperatures, such as from −30° C. to +50° C., and some applications may operate over an even wider range, such as −40° C. to +100° C. The changes in temperature, however, can cause slight changes in the wavelength emitted by the VCSEL. For some applications, such variations in the wavelength are unacceptable. Thus, it is desirable to develop improvements to stabilize the wavelength of the optical signal emitted by the VCSELs.

### SUMMARY

The present disclosure describes VCSELs that include a sub-wavelength grating.

For example, in one aspect, a VCSEL includes a substrate and an epitaxial VSCEL structure on the substrate. The epitaxial VSCEL structure includes a resonant cavity, including a gain region, disposed between a first reflector and a partially reflecting second reflector. At least one of the first or second reflectors includes a first sub-wavelength grating to provide spectral control for optical emission from the VCSEL. Preferably, the first sub-wavelength grating is operable to lock a wavelength of an optical beam for emission from the VCSEL substantially to a wavelength defined by the grating.

Some implementations include one or more of the following features. For example, in some instances, the first sub-wavelength grating is operable to lock a wavelength of an optical beam for emission from the VCSEL substantially to a wavelength defined by the grating. The first sub-wavelength grating can be, for example, a resonant waveguide grating. The VCSEL can be, for example, a top-emitting VCSEL or a bottom-emitting VCSEL. In some implementations, the first sub-wavelength grating is disposed on a side of the gain region opposite a side on which the substrate is disposed. A second sub-wavelength grating may be disposed on a same side of the gain region as the substrate. In some cases, the first sub-wavelength grating is disposed on the same side of the gain region as the substrate.

In some implementations, each of the first and second sub-wavelength gratings is a narrow band reflector whose reflectance curves have substantially a same peak. The partially reflecting second reflector can include the first sub-wavelength grating. In some instances, the VCSEL includes a phase matching layer adjacent the first sub-wavelength grating. The phase matching layer can be composed, for example, of AlGaAs. In some cases, at least one of the first or second reflectors includes a distributed Bragg reflector. Further, in some instances, at least one of the first or second reflectors includes the first sub-wavelength grating and further includes a distributed Bragg reflector. Each of the first and second reflectors may include a respective sub-wavelength grating. In some implementations, at least one of the first or second reflectors further includes a distributed Bragg reflector. A phase matching layer may be provided adjacent at least one of the first or second sub-wavelength gratings. In some cases, a respective phase matching layer is adjacent each of the first and second sub-wavelength gratings. In some implementations, the first sub-wavelength grating is composed of silicon nitride (SiN), silicon oxide (SiO₂) or silicon oxynitride (SiOxN_{y}).

Various advantages can be attained in some implementations. For example, in some cases, stable wavelength locking over a wide range of operating temperatures can be achieved, which can be beneficial for many applications.

The present disclosure also describes an optical sensor module including an optical source including a VCSEL as described herein. The VCSEL is operable to generate a source beam directed through a window toward an object. The module includes an optical detector to sense light reflected back from the object illuminated by the narrow divergence source beam. A computation device is operable to determine a distance to the object or a physical characteristic of the object based at least in part on a signal from the optical detector.

The optical sensor module can be incorporated into a host device (e.g., a smart phone), wherein the host device is operable to use data obtained by the optical detector of the optical sensor module for one or more functions executed by the host device.

Modules and host devices that include one or more VCSELs as described here may obtain more accurate data in some cases, and the data can be used for functions executed, for example, by the host device. These and other functions can be more accurately performed, thereby conferring substantial advantages to the host device itself.

Other aspects, features and advantages will be readily apparent from the following detailed description, the accompanying drawings, and the claims.

### BRIEF DESCRIPTION OF THE DRAWINGS

FIGS. 1-6 illustrate examples of top-emitting VCSELs that include one or more sub-wavelength gratings.

FIGS. 7-15 illustrate examples of bottom-emitting VCSELs that include one or more sub-wavelength gratings.

FIG. 16 illustrates an example of a proximity sensor module incorporating a VCSEL that includes one or more sub-wavelength gratings.

FIG. 17 illustrates an example of a host device incorporating a module that includes a VCSEL having one or more sub-wavelength gratings.

### DETAILED DESCRIPTION

An example of a known VCSEL device includes an epitaxial structure over a semiconductor substrate. The epitaxial structure includes a resonant cavity having a gain region disposed, for example, between reflectors, at least one of which is partially reflecting so as to allow an output beam to exit the device. The reflectors for the resonant cavity sometime are implemented as distributed Bragg reflector (DBR) mirrors.

In accordance with the present disclosure, the epitaxial structure is modified to incorporate one or more sub-wavelength diffractive gratings, which in some cases are sub-wavelength resonant waveguide gratings (RWGs). In general, a RWG includes at least one waveguide layer and a diffraction grating, although these may overlap in some cases. The grating has a periodic sub-wavelength structure of alternating refractive indices. Resonance occurs when the grating couples the incident light to the modes of the waveguide, which happens only for a certain wavelength band and angle of incidence, depending on the grating parameters and the refractive indices of the surrounding media. In the present context, the a sub-wavelength grating means that the period “d” of the grating is so small compared to the resonant wavelengths that substantially only the zeroth diffraction order propagates.

In some instances, the sub-wavelength gratings provide spectral control. For example, in some implementations, the sub-wavelength grating is designed for narrowband reflection, which can help lock the wavelength of the emitted laser beam and can help reduce sensitivity of the VCSEL's wavelength to changes in temperature. In some cases, including a sub-wavelength grating in the VCSEL structure can achieve stable wavelength locking for a wide range of operating temperatures (e.g., −40° C. to +100° C.) Incorporating the sub-wavelength grating can, in some cases, not only reduce the spectral width of the VCSEL, but also may reduce spectral variance originating from thickness of concentration differences across the wafer used during fabrication of the devices. The foregoing details may differ for other implementations.

In some instances, at least one of the DBR mirrors is replaced with a respective sub-wavelength grating (e.g., a sub-wavelength grating with or without a waveguide layer). In such cases, the respective DBR mirror can be omitted from the epitaxial structure. In some cases, at least one of the sub-wavelength gratings is combined with a respective DBR mirror having a sufficiently low reflectivity such that the DBR mirror alone (i.e., in the absence of the associated sub-wavelength grating) would not achieve lasing of the VCSEL. Combining the DBR mirror with a sub-wavelength grating can, in some cases, help realize a thinner VCSEL with lower electrical and/or thermal resistance and lower absorption losses.

One or more sub-wavelength gratings can be incorporated into top-emitting VCSELs as well as bottom-emitting VCSELs. In the latter type of VCSEL, the laser beam is emitted through the VCSEL substrate. The following discussion, in conjunction with the associated drawings, illustrates various examples. In each of the examples described below, the sub-wavelength grating can have a RWG grating structure (i.e., including a waveguide layer) or a grating structure without a waveguide layer.

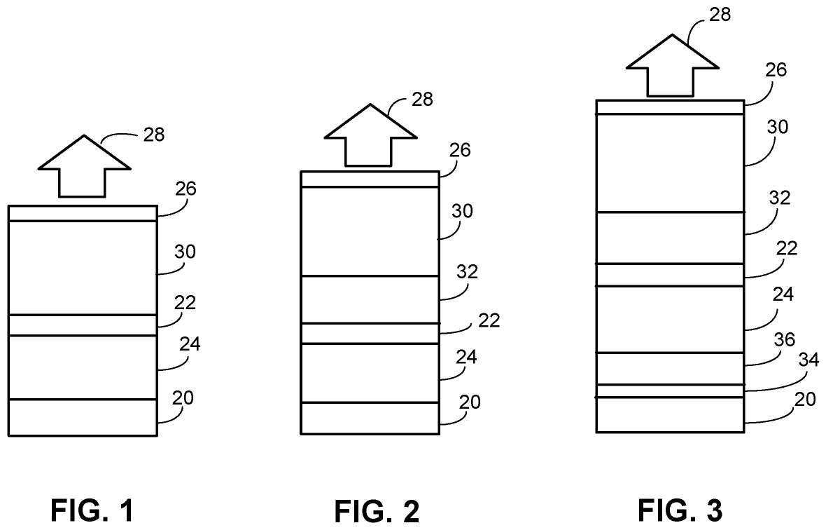

FIG. 1 illustrates a top-emitting VCSEL that includes a semiconductor substrate 20 composed, for example, of GaAs. The VCSEL has an epitaxial structure over the semiconductor substrate 20. The epitaxial structure includes a resonant cavity having a gain region 22, disposed between mirrors. In the example of FIG. 1, the bottom mirror is implemented as a highly reflecting DBR mirror 24, whereas the upper mirror is implemented as a partially reflecting sub-wavelength grating 26 so as to allow an output beam 28 to exit the device. The gain region 22 can comprise, for example, a stack of multiple quantum wells. The gain (i.e., active) region 22 is activated by a current flowing between top and bottom contacts (e.g., electrodes). In some implementations, an aperture is used to concentrate the current in the center region. This aperture can be formed, for example, by oxidation, although other techniques such as ion implantation can be used to form the electrically insulating region around the aperture. The high gain results in laser oscillation between the mirrors 24, 26.

As shown in FIG. 1, the VCSEL also can include a phase matching layer 30 between the sub-wavelength grating 26 and the gain region 22. The phase matching layer 30 can be an epitaxially grown layer having a thickness, for example, up to 100 μm. In some instances, the phase matching layer 30 can be thicker and can be grown by other techniques. Incorporating the phase matching layer 30 can provide various advantages in some implementations. For example, the presence of the phase matching layer 30 can facilitate adjusting of the intra-cavity phase of the standing wave to fulfill the standing wave condition for lasing operation and to optimize the standing field pattern to overlap with the gain section. The phase matching layer 30 also can permit control of longitudinal mode spacing and can be used to control transverse modes to reduce divergence.

FIG. 2 illustrates another example of a top-emitting VCSEL that is similar to the VCSEL of FIG. 1, but also includes a second DBR mirror 32 disposed between the gain region 22 and the phase matching layer 30. The second DBR mirror 32 is partially reflecting and has a reflectivity such that the DBR mirror 32 alone (i.e., in the absence of the associated sub-wavelength grating 26) would not achieve lasing of the VCSEL.

FIG. 3 illustrates yet another example of a top-emitting VCSEL that is similar to the VCSEL of FIG. 2, but also includes a second sub-wavelength grating 34 as well as a second phase matching layer 36 disposed between the second grating 34 and the gain region 22. Thus, the VCSEL of FIG. 3 includes a DBR mirror 32, a phase matching layer 30 and a grating 26 on one side of the gain region 22, and also includes a DBR mirror 24, a phase matching layer 36 and a grating 34 on the other side of the gain region 22.

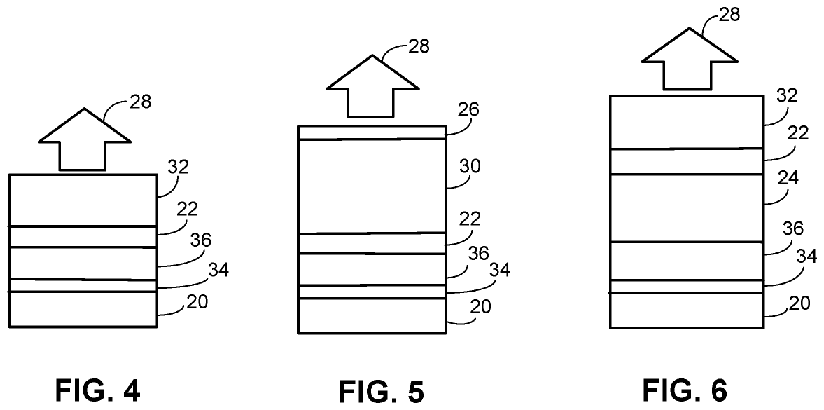

FIG. 4 illustrates an example of a top-emitting VCSEL that, like FIG. 1, includes a sub-wavelength grating 34 and phase matching layer 36 on one side of the gain region 22, and a DBR mirror 32 on the other side of the gain region 22. However, in the VCSEL of FIG. 4, the grating 34 and phase matching layer 36 are disposed between the substrate 20 and the gain region 22.

FIG. 5 also illustrates another example of a top-emitting VCSEL. In contrast to FIG. 4, a second sub-wavelength grating 26 and phase matching layer 30 are disposed over the gain region 22, instead of the DBR mirror 32. Thus, the implementation of FIG. 5 has respective a sub-wavelength grating (34 or 26) and a respective phase matching layer (36 or 30) on each side of the gain region 22.

FIG. 6 illustrates a further example of a top-emitting VCSEL. In contrast to FIG. 4, a second DBR mirror 24 is disposed between the gain region 22 and the phase matching layer 36. Thus, the implementation of FIG. 6 has a respective DBR mirror (24 or 32) on each side of the gain region 22.

In implementations that include a respective sub-wavelength grating 26, 34 on both sides of the gain region 22 (e.g., FIGS. 3 and 5), both of the gratings 26, 34 can be narrow band reflectors whose reflectance curves have substantially the same peak. In other cases, one of the gratings 26, 34 may be a narrow band reflector to facilitate wavelength locking, whereas the other grating may be a broadband reflector that provides, for example, better optical efficiency.

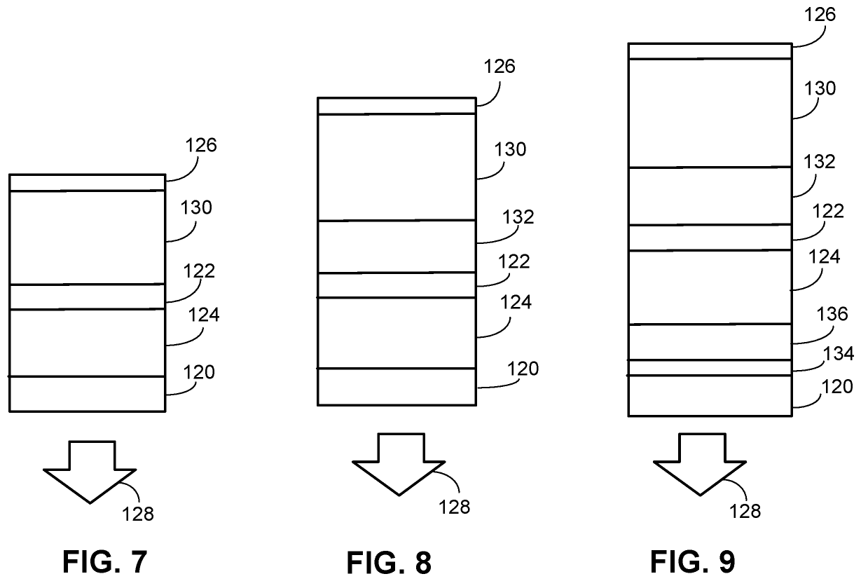

FIG. 7 illustrates a bottom-emitting VCSEL that includes a semiconductor substrate 120 composed, for example, of GaAs. The VCSEL has an epitaxial structure over the semiconductor substrate 120. The epitaxial structure includes a resonant cavity having a gain region 122, disposed between mirrors. In the example of FIG. 7, the bottom mirror is implemented as a partially reflecting DBR mirror 124 so as to allow an output beam 28 to exit the device, whereas the upper mirror is implemented as a highly reflecting sub-wavelength grating 126. The gain region 122 can comprise, for example, a stack of multiple quantum wells. The gain (i.e., active) region 122 is activated by a current flowing between top and bottom contacts (e.g., electrodes). In some implementations, an aperture is used to concentrate the current in the center region. This aperture can be formed, for example, by oxidation, although other techniques such as ion implantation can be used to form the electrically insulating region around the aperture. The high gain results in laser oscillation between the mirrors 124, 126.

As shown in FIG. 7, the VCSEL also can include a phase matching layer 130 having features and providing advantages as described above for the phase matching layer 30. The phase matching payer 130 is disposed between the sub-wavelength grating 126 and the gain region 122.

FIG. 8 illustrates another example of a bottom-emitting VCSEL that is similar to the VCSEL of FIG. 7, but also includes a second DBR mirror 132 disposed between the gain region 122 and the phase matching layer 130. The second DBR mirror 132 is partially reflecting and has a reflectivity such that the DBR mirror 132 alone (i.e., in the absence of the associated sub-wavelength grating 126) would not achieve lasing of the VCSEL.

FIG. 9 illustrates yet another example of a bottom-emitting VCSEL that is similar to the VCSEL of FIG. 8, but also includes a second sub-wavelength grating 134 as well as a second phase matching layer 316 disposed between the second grating 134 and the gain region 22. Thus, the VCSEL of FIG. 9 includes a DBR mirror 132, a phase matching layer 130 and a grating 126 on one side of the gain region 122, and also includes a DBR mirror 124, a phase matching layer 136 and a grating 134 on the other side of the gain region 122.

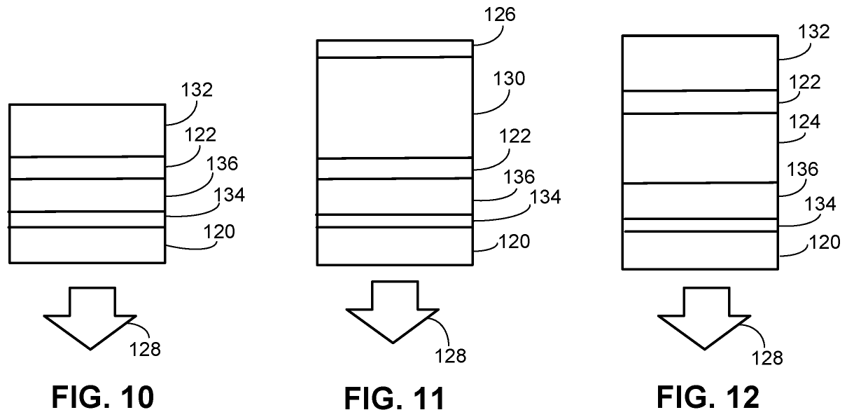

FIG. 10 illustrates an example of a bottom-emitting VCSEL that, like FIG. 7, includes a sub-wavelength grating 134 and phase matching layer 136 on one side of the gain region 122, and a DBR mirror 132 on the other side of the gain region 122. However, in the VCSEL of FIG. 10, the grating 134 and phase matching layer 136 are disposed between the substrate 120 and the gain region 122.

FIG. 11 also illustrates another example of a bottom-emitting VCSEL. In contrast to FIG. 10, a second sub-wavelength grating 126 and phase matching layer 130 are disposed over the gain region 122, instead of the DBR mirror 132. Thus, the implementation of FIG. 11 has respective a grating (134 or 126) and a respective phase matching layer (136 or 130) on each side of the gain region 122.

FIG. 12 illustrates a further example of a bottom-emitting VCSEL. In contrast to FIG. 10, a second DBR mirror 124 is disposed between the gain region 122 and the phase matching layer 136. Thus, the implementation of FIG. 12 has a respective DBR mirror (124 or 132) on each side of the gain region 122.

In implementations that include a respective grating 126, 134 on both sides of the gain region 122 (e.g., FIGS. 9 and 11), both of the gratings 126, 134 can be narrow band reflectors whose reflectance curves have substantially the same peak. In other cases, one of the gratings 126, 134 may be a narrow band reflector to facilitate wavelength locking, whereas the other grating may be a broadband reflector that complements one or more features of the narrow band grating such that the combination results in better optical performance, reflectance, polarization and/or efficiency.

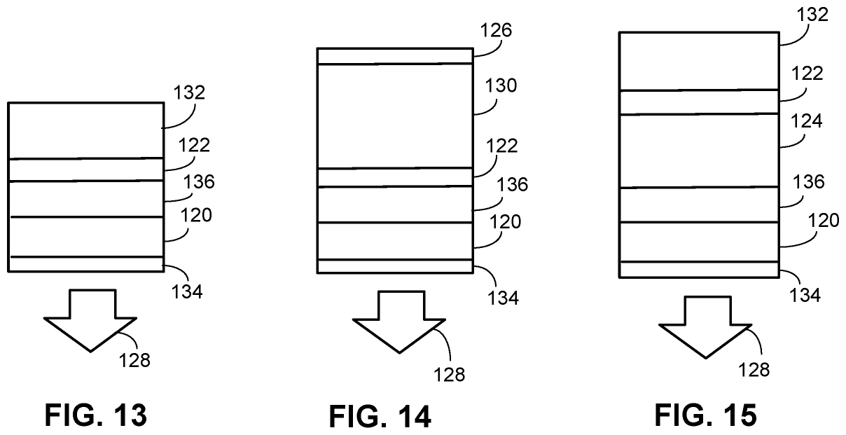

In some implementations, as shown in FIGS. 13, 14 and 15, the sub-wavelength grating 134 is disposed on the bottom surface of the substrate 120. As shown in these examples of bottom-emitting VCSELs, the grating 134 is disposed on the side of the substrate 120 opposite the side of the substrate 210 on which the gain region 122 is disposed. In some implementations, the phase matching layer 130, 136 may be omitted.

Various materials can be used for the sub-wavelength grating(s) 26, 34, 126, 134. Examples include silicon nitride (SiN), silicon oxide (SiO₂) and/or silicon oxynitride (SiOₓN_{y}), where the oxygen to nitrogen ration is adjusted for a close-to-zero coefficient of expansion. The grating parameters can include, among others, refractive index, the grating period, and the height and width of the grating layers. In some cases, the grating has a thickness in a range of 100-1,000 nm. However, this may differ for other implementations.

In some implementations, one or more of the phase matching layers 30, 36, 130, 136 are composed of aluminum gallium arsenide (AlGaAs). However, other materials (e.g., semiconductor compounds) that are transparent to the operating wavelength of the VCSEL can be used in some instances.

In some instances, the gain region 22 can be increased in length by using multiple gain sections instead of just a single gain section group of multiple quantum wells. The gain sections can be separated from one another by tunnel junction(s), with each gain section being placed at the maximum intensity point of the resonant cavity standing wave so that the cavity length increases in half wavelengths by the number of added gain sections. The resulting VCSEL device can have a lower divergent beam because of the longer cavity, and also can have higher intensity because of the higher gain from the multiple gain sections.

In some implementations, the sub-wavelength grating(s) may be designed so that the VCSEL's output beam has a bandwidth of no more than about 4 nm (centered, e.g., about 975 nm) at 99% reflectivity, and the VCSEL may have a temperature sensitivity of 0.01 nm/deg.° C. or less. The foregoing features may differ for other implementations.

The wavelength acceptance range (i.e., the natural operating wavelength of the VCSEL without locking to the sub-wavelength grating) may be, for example, as large as 10 nm or even greater in some cases, yet the VCSEL can still be locked substantially to the grating wavelength.

In some cases, the grating(s) can be used to suppress higher order multi-modes so as to increase power in a very low divergence single-mode operation. For example, the grating(s) can be designed to allow for only close-to-zero angle of incidence. For example, the grating(s) can be designed to have peak reflection for a narrow range of incidence angles.

As the electrical resistance of the grating(s) typically will be lower than that of DBR mirrors, the efficiency of the VCSELs can, in some instances, be increased significantly.

Multiple VCSELs as described above can be integrated into a VCSEL array. For example, the VCSELs in the array may be regularly spaced so that they are arranged in a regular pattern or randomly spaced so that they are in a random arrangement. The VCSELs can be connected by respective electrical connections to respective electrical contacts such that the VCSELs are addressable, and can be activated or deactivated, either individually or in groups.

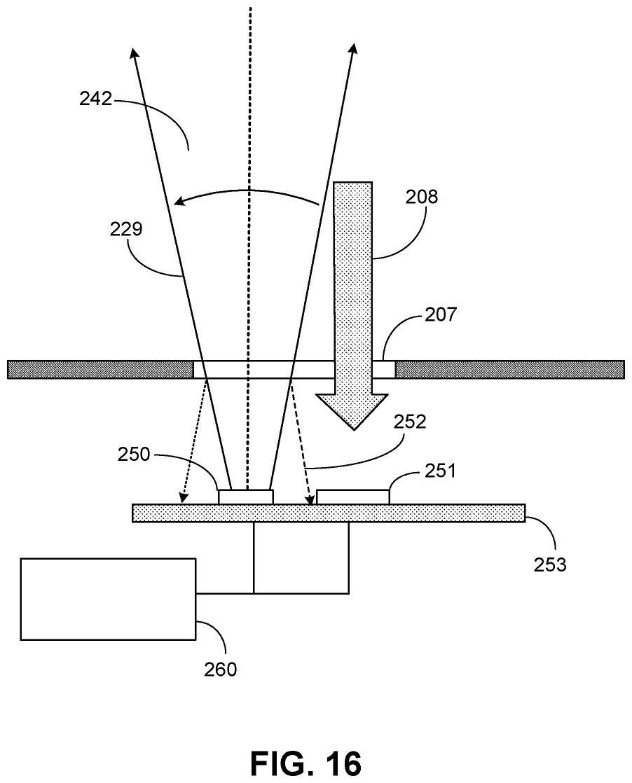

FIG. 16 illustrates an example of a proximity sensor module that includes a VCSEL source including one or more VCSELs such as those described above (e.g., FIGS. 1-15). The VCSEL source 250 and a light detector (e.g., a photodetector) 251 are mounted close together on a common substrate 253. The VCSEL beam propagates out through a window 107 and reflects and scatters off an object outside the module. A portion of the backscatter radiation 208 returns through the window 207 and is captured by the detector 251. The signal intensity from the detector is used by processing circuitry to determine the distance of the object from the sensor. In the illustrated example, the VCSEL beam divergence is sufficiently small that the specular reflection 252 from the window 207 returns close to the VCSEL and does not fall on the detector 251. Thus, this reflection 252 does not add a noise signal to modify the backscatter signal received by the detector 251 and so does not degrade the distance determination.

The illustrated optical sensor module thus includes, as an optical source, a VCSEL device operable to generate a source beam directed through a window toward an object. The module further includes an optical detector to sense light reflected back from the object illuminated by the source beam, and a computation device 260 including processing circuitry operable to determine a distance to the object or a physical characteristic of the object based at least in part on a signal from the optical detector. The processing circuitry can be implemented, for example, as one or more integrated circuits in one or more semiconductor chips with appropriate digital logic and/or other hardware components (e.g., read-out registers; amplifiers; analog-to-digital converters; clock drivers; timing logic; signal processing circuitry; and/or microprocessor). The processing circuitry is, thus, configured to implement the various functions associated with such circuitry.

As the VCSEL device in the module can include at least one sub-wavelength grating designed for narrowband reflection, the module can exhibit reduced sensitivity of the VCSEL's wavelength to changes in temperature. In some cases, stable wavelength locking for a wide range of operating temperatures can be achieved, which can be beneficial for many applications.

The foregoing description is made in relation to proximity sensing of objects for applications such as self-focusing of cameras and other motion detection applications. However, other applications of the technology will be readily apparent. For example, the very low divergence VCSEL source beam also can be used for health monitoring by measuring, e.g., blood flow, heart pulse rate and/or chemical composition. In these applications, the source beam is directed at the sample or object, and the detector measures quantity of reflected light at one or more wavelengths or fluctuation of reflected light which correlates with pulsing effects from a heart-beat. It can be equally important in these other applications for the VCSEL to exhibit stable wavelength emission. The sensitivity of these applications likewise can be improved by incorporating the technology of this disclosure. The present technology also can be useful, for example, for other optical sensing modules, such as for gesture sensing or recognition.

VCSELs including one or more sub-wavelength gratings as described above, or modules incorporating one or more such VCSELs, can be integrated into a wide range of host devices such as smartphones, laptops, wearable devices, other computers, and automobiles. The host devices may include processors and other electronic components, and other supplemental modules configured to collect data, such as cameras, time-of-flight imagers. Other supplemental modules may be included such as ambient lighting, display screens, automotive headlamps, and the like. The host devices may further include non-volatile memory where instructions for operating the optoelectronic modules, and in some instances the supplemental modules, are stored.

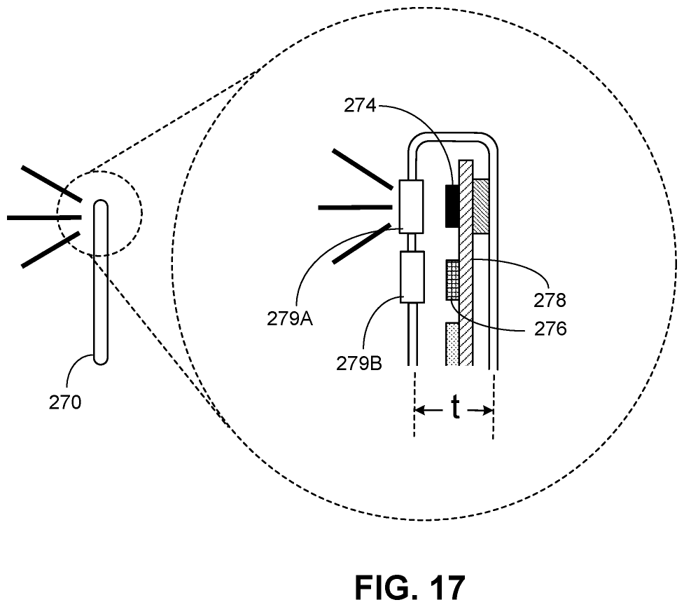

FIG. 17 illustrates a smartphone 270 as an example of a host device that includes a module for three-dimensional optical imaging and/or sensing. The module is operable to emit light and to detect incoming beams. The module includes a VCSEL light source 274 including at least one sub-wavelength grating as described above. The module further includes a sensor 276 operable to sense incoming beams. The VCSEL light source 274 and the sensor 276 can be mounted, for example, on a printed circuit board or other substrate 278. The module also can include projection optics 279A and/or collection optics 279B, which can be implemented, for example, as lenses or other passive optical elements. Signal processing circuitry is operable to process signals detected by the sensor 276 and to determine, for example, the distance to an object outside the smartphone 270 that reflects some of the light back toward the smartphone, and/or for gesture recognition.

As modules using the VCSELs described above can obtain more accurate data in some cases, and the data can be used for functions executed by the smartphones (e.g., screen response to user proximity), these and other functions can be more accurately performed, thereby conferring substantial advantages to the smartphone or other host device itself.

In some cases, multiple VCSELs, as described above, can be incorporated into an array of VCSELs. In some implementations, one or more VCSELs are arranged in a module operable to produce structured light.

Although a broad framework of the disclosure is described with reference to a few preferred embodiments, other implementations may be configured by applying combinations and sub-combinations of elements described in this disclosure. Further, in some cases, features described in connection with different embodiments can be combined in the same implementation. Accordingly, other implementations are within the scope of the claims.

1. A vertical cavity surface emitting laser (VCSEL) comprising:
a substrate;
an epitaxial VSCEL structure on the substrate, wherein the epitaxial VSCEL structure includes a resonant cavity, including a gain region, disposed between a first reflector and a partially reflecting second reflector, wherein at least one of the first or second reflectors includes a first sub-wavelength grating to provide spectral control for optical emission from the VCSEL.

2. The VCSEL of claim 1 wherein the first sub-wavelength grating is operable to lock a wavelength of an optical beam for emission from the VCSEL substantially to a wavelength defined by the grating.

3. The VCSEL of claim 1 wherein the first sub-wavelength grating is a resonant waveguide grating.

4. The VCSEL of claim 1 wherein the VCSEL is a top-emitting VCSEL.

5. The VCSEL of claim 1 wherein the VCSEL is a bottom-emitting VCSEL.

6. The VCSEL of claim 1 wherein the first sub-wavelength grating is disposed on a side of the gain region opposite a side on which the substrate is disposed.

7. The VCSEL of claim 6 further including a second sub-wavelength grating on a same side of the gain region as the substrate;
wherein each of the first and second sub-wavelength gratings is a narrow band reflector whose reflectance curves have substantially a same peak.

8. (canceled)

9. The VCSEL of claim 1 wherein the first sub-wavelength grating is disposed on a same side of the gain region as the substrate.

10. The VCSEL of claim 1 wherein the partially reflecting second reflector includes the first sub-wavelength grating.

11. The VCSEL of claim 1 further including a phase matching layer adjacent the first sub-wavelength grating;
wherein the phase matching layer is composed of AlGaAs.

12. (canceled)

13. The VCSEL of claim 1 wherein at least one of the first or second reflectors includes a distributed Bragg reflector.

14. (canceled)

15. The VCSEL of claim 1 wherein each of the first and second reflectors includes a respective sub-wavelength grating.

16. The VCSEL of claim 15 wherein at least one of the first or second reflectors further includes a distributed Bragg reflector.

17. The VCSEL of claim 15 wherein each of the first and second reflectors further includes a respective distributed Bragg reflector.

18. The VCSEL of claim 15 including a phase matching layer adjacent at least one of the first or second sub-wavelength gratings.

19. The VCSEL of claim 15 including a respective phase matching layer adjacent each of the first and second sub-wavelength gratings.

20. The VCSEL of claim 1 wherein the first sub-wavelength grating is composed of silicon nitride (SiN), silicon oxide (SiO₂) or silicon oxynitride (SiOₓN_{y}).

21. An optical sensor module comprising:
an optical source including a VCSEL according to claim 1, the VCSEL being operable to generate a source beam directed through a window toward an object;
an optical detector to sense light reflected back from the object illuminated by the narrow divergence source beam; and
a computation device operable to determine a distance to the object or a physical characteristic of the object based at least in part on a signal from the optical detector.

22. A host device comprising an optical sensor module according to claim 21, wherein the host device is operable to use data obtained by the optical detector of the optical sensor module for one or more functions executed by the host device.

23. The host device of claim 22 wherein the host device is a smart phone.
